(19) United States
(12) Patent Application Publication
(10) Pub. No.: US 2026/0223328 A1
(43) Pub. Date: Jul. 30, 2026

(54) BOILERPLATE ASSEMBLY FOR TWO-PHASE IMMERSION COOLING

(71) Applicant: HEWLETT PACKARD ENTERPRISE DEVELOPMENT LP, Spring, TX (US)

(72) Inventors: Anil Yuksel, Houston, TX (US); Steven Dale Webster, Montgomery, TX (US); Keith Allen Sauer, Spring, TX (US)

(21) Appl. No.: 19/040,592

(22) Filed: Jan. 29, 2025

(51) Int. Cl. H05K 7/20

(52) U.S. Cl. CPC H05K 7/20309; H05K 7/203; H05K 7/20809

(57) ABSTRACT

A boilerplate assembly for two-phase immersion cooling of an information processing system comprises a boilerplate and a manifold attached to the boilerplate. The boilerplate comprises a first face and a second face opposite the first face. The first face is thermally coupled with a processor or other component of an information processing system. The second face is configured to, in an immersed state of the system in an immersion cooling tank, contact and facilitate boiling of liquid coolant. The manifold comprises multiple nozzles and is to receive an input stream of the liquid coolant from the pool and expel multiple output streams of the liquid coolant back into the pool via the nozzles. The nozzles direct the output streams towards the second face of the boilerplate. The streams may disrupt a mixed flow region at the second face and thereby enhance the rate of boiling.

### INTRODUCTION

Information processing systems, such as servers and networking devices, are usually provided with cooling systems to remove heat and keep the components of the system within desired operation temperature ranges. Immersion cooling is one cooling approach which is gaining popularity as an alternative to traditional air-cooling systems and direct liquid cooling (DLC) systems. Immersion cooling involves submerging an information processing system in an electrically non-conductive (e.g., dielectric) liquid coolant, usually contained in a large tank which can hold multiple immersed systems concurrently. Unlike DLC where the liquid is contained within a closed loop and is not exposed directly to electrical components of the system, in immersion cooling the liquid coolant spreads throughout the system and directly contacts all the exposed components thereof. The liquid coolant can thus absorb heat from essentially all of the components of the system. The absorbed heat is then moved out of the individual system via convection of the liquid through the tank. A cooler, such as a heat exchanger, may be provided at the tank level to remove the heat from the liquid.

Immersion cooling can include single-phase and two-phase immersion cooling. In single-phase immersion cooling, the coolant is in liquid form throughout operation (excluding negligible amounts of vapor which may form). In two-phase immersion cooling, portions of the coolant cyclically convert between liquid and vapor (gas) phases during operation. The coolant is selected such that its boiling point is near a desired operating temperature for the components, such that as the component's temperature approaches the desired operating temperature the component will begin boiling (converting from liquid to vapor/gas) the coolant in contact therewith. The boiling of the coolant absorbs a great deal of heat from the component due to the latent heat of vaporization, thus cooling the component. The more heat the component generates, the more rapidly the boiling will occur, and therefore the more heat will be absorbed by the coolant from the component. Thus, assuming the boiling can occur rapidly enough to keep up with the amount of heat being generated, the temperature of the component will not rise substantially above the boiling point of the coolant. In two-phase cooling, the tank may be sealed to prevent the vapor from escaping. The vapor is then cooled by a cooling device, which condenses the coolant back to liquid form, and the condensed liquid coolant then falls back down into the pool of liquid phase coolant, ready to be used for another cycle of heat absorption and transportation.

### BRIEF DESCRIPTION OF THE DRAWINGS

The present disclosure can be understood from the following detailed description, either alone or together with the accompanying drawings. The drawings are included to provide a further understanding of the present disclosure and are incorporated in and constitute a part of this specification. The drawings illustrate one or more examples of the present teachings and together with the description explain certain principles and operations. In the drawings:

FIG. 1 is a schematic diagram illustrating an immersion cooling system, information processing device, and boilerplate assembly.

FIG. 2 is a perspective view of an example boilerplate assembly.

FIG. 3 is another perspective view of the boilerplate assembly of FIG. 2.

FIG. 4 is a side view of the boilerplate assembly of FIG. 2.

FIG. 5 is a cross-section of the boilerplate assembly of FIG. 2, with the section taken along the line 5-5 indicated in FIG. 3.

FIG. 6 is a cross-section of the boilerplate assembly of FIG. 2, with the section taken along the line 6-6 indicated in FIG. 4.

FIG. 7 is another perspective view of the boilerplate assembly of FIG. 2.

FIG. 8 is a perspective view of an example information processing system comprising two of the boilerplate assemblies of FIG. 2.

FIG. 9 is a cross-section of an immersion cooling system comprising the information processing system comprising of FIG. 8 immersed in an immersion cooling tank.

### DETAILED DESCRIPTION

Immersion cooling is gaining popularity as an alternative to air cooling and DLC for a number of reasons. For example, CPUs and other components are increasing in heat generation, which is making it increasingly difficult to efficiently cool systems via airflow. In some high-power systems, it might not be possible for fans to adequately dissipate the amount of heat being generated. In other systems, it is possible for the fans to dissipate the heat but doing so may require the fans to run at high speed, which increases their power consumption and noise generation, making the cooling inefficient. In contrast, immersion cooling tanks generally include far fewer actively driven (powered) cooling elements, and thus they can provide cooling with substantially less power consumption and less noise generation.

For example, the powered cooling components of some immersion cooling tanks may be limited to just one or a few pumps, which may, for example, drive some bulk circulation of the liquid through the tank and through the cooler of the tank. A single tank may hold multiple servers, in some instances as many as could be held by a conventional rack (e.g., around twenty 2U-servers, in some cases). Thus, in some cases, only a few powered cooling components are needed to provide cooling for many servers. In contrast, an air-cooled rack with a comparable number of servers as the tank may require multiple dozens of fans—for example, assuming the rack has about twenty 2U-servers, over a hundred fans may be present. Thus, the immersion cooling tank will draw much less power, and generate much less noise, than the comparable air-cooled rack.

In addition, DLC generally requires a sophisticated closed cooling loop to be provided to circulate liquid coolant through the information processing systems, with the cooling loop comprising tubes, valves, pumps, cold plates, leak detection devices, and many other pieces of liquid cooling infrastructure. In the case of a rack with multiple servers, the overall liquid cooling loop for the rack may include multiple sub-loops, one for each individual system in the rack. Thus, DLC solutions tend to be very expensive and complicated to implement, and accordingly DLC has usually been reserved for high-power and high-cost systems, such as high-performance compute (HPC) systems (aka supercomputers), where the cost can be justified. Often, DLC is used for cooling the highest power components, such as CPUs. This in itself can be costly. Furthermore, in some systems DLC is also used for cooling the myriad other components that are dispersed throughout the system. This greatly increases the costs and complexity of the cooling solution, as every component needs to be thermally coupled to the liquid cooling loop and there are many components with irregular shapes, disparate locations, and varying cooling needs. To reduce some of the cost and complexity, some systems will use DLC to cool just high-powered components (e.g., CPUs) and will include air cooling to cool the other ancillary components. While this hybrid approach can be effective, the DLC components can still be costly and complicated (albeit less so than in a DLC-only system) and the air-cooling components suffer from the same drawbacks as air-cooled system (high power consumption and noise generation).

In contrast, immersion cooling generally does not require the large and complicated custom liquid cooling loops and associated infrastructure often needed for DLC, which can make immersion cooling less costly and complicated to implement in the long run. In addition, because immersion cooling allows the coolant to spread throughout the system and contact all exposed components, no special effort or cost is required to ensure that the non-CPU components receive cooling along with the CPUs.

However, while immersion cooling can be effective at cooling many systems, in some cases, individual high-power components with concentrated heat generation, such as some very hot CPUs, may receive less cooling than may be desired in standard immersion cooling tanks. In particular, the rate of convection (the transfer of heat through liquids) through the tank may limit how much heat can be absorbed from some high-power components. Using two-phase immersion cooling can improve heat transfer rates as compared to single-phase, as two-phase immersion takes advantage of the latent heat of vaporization to allow heat to be absorbed by the coolant at a greater rate, but even with two-phase cooling it is possible that less cooling than may be desired might be provided for certain high-heat components. For example, if the amount of heat being generated by a component outpaces the rate at which the liquid in contact with the component can boil off and remove the heat, then the temperature of the component may start to rise above the boiling point of the coolant and eventually approach its maximum temperature. This can result in performance being throttled to avoid overheating.

To address these issues, disclosed herein is a boilerplate assembly for efficient two-phase immersion cooling of high-heat components of an information processing device, such as the CPU. The boilerplate assembly has a thermally conductive boilerplate with a first face that thermally couples with the CPU (or other high-heat component) to absorb heat therefrom and a second face that is exposed to the liquid phase coolant and transfers the heat absorbed from the CPU into the coolant, causing the coolant to boil. The boilerplate has a greater surface area than the CPU (or other component), thus allowing for more contact with the liquid and thus a greater rate of boiling, which in turn increases the rate at which heat can be extracted from the component, providing better cooling. The second face of the boilerplate may also comprise, in some examples, a mesh structure configured to further increase the rate at which the coolant boils. In addition, the boilerplate assembly includes a manifold attached to the boilerplate and fluidically coupled with a pump that draws in liquid coolant from the tank and forces the coolant to flow through the manifold. The manifold has nozzles arranged to expel the liquid coolant in high velocity streams directed towards the second face of the boilerplate. These streams of coolant disturb the mixed flow region in and around the second face (a region where vapor and liquid mix), thereby changing the boiling characteristics of the region in a way which can further increase the rate of boiling, and thus further improve thermal performance. Furthermore, the streams of coolant also create forced convection of the liquid phase coolant in the region, which further reduces thermal resistance and increases thermal performance. Thus, the boilerplate assembly allows for the temperatures of the high-power components to be greatly reduced as compared to a passive two-phase immersion cooling without the boilerplate assembly.

Turning now to the figures, various devices, systems, and methods in accordance with nonlimiting aspects of the present disclosure will be described.

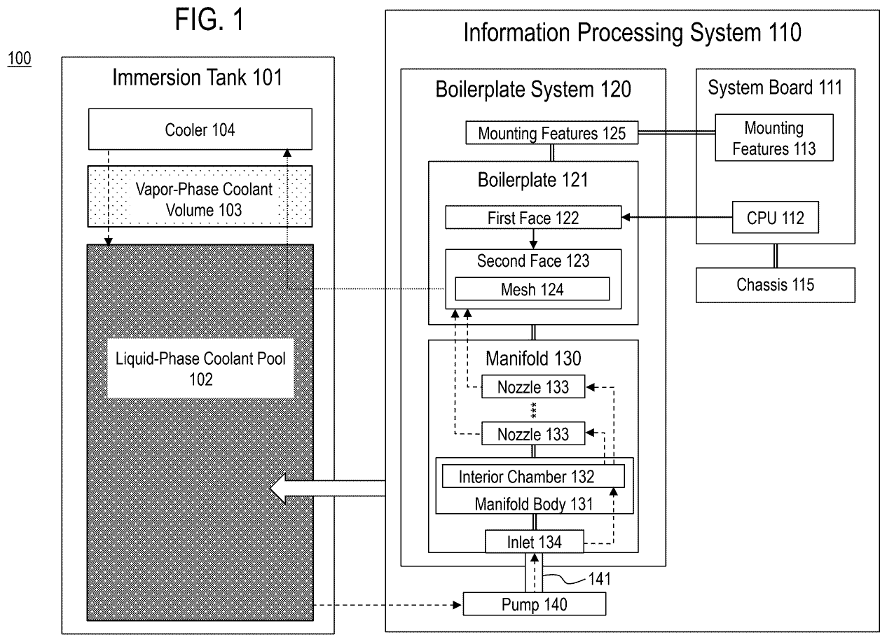

FIG. 1 is a schematic diagram conceptually illustrating a system 100 comprising an immersion cooling tank 101 and an information processing system 110 which includes a boilerplate assembly 120. FIG. 1 is schematic and conceptual in nature and is not intended to illustrate spatial relationships, shapes, dimensions, or other structural details unless otherwise mentioned. Moreover, FIG. 1 is not intended to exhaustively depict all aspects of the systems 100 and 110 or of the assembly 120. Moreover, the numbers and arrangements of the illustrated elements are not limiting. In other words, in some implementations of the systems 100 or 110 or of the assembly 120, the elements illustrated in FIG. 1 may be included in numbers and/or arrangements that differ from the illustrated numbers or arrangements. Also, some implementations of the systems 100 or 110 or of the assembly 120 may include elements that are not illustrated in FIG. 1, and/or may some may omit one or more of the elements that are illustrated in FIG. 1. Furthermore, although the information processing system 110 is shown in FIG. 1 in association with the immersion tank 101 (as part of the system 100), it should be understood that in some examples disclosed herein the information processing system 110 is provided separately without the immersion tank present. Furthermore, although the boilerplate assembly 120 is shown in FIG. 1 as an installed component of the information processing system 110, in some examples disclosed herein the boilerplate assembly 120 is provided separately from the rest of the information processing system 110. In other words, some examples disclosed herein comprise the full system 100 as illustrated in FIG. 1, other examples comprise just the information processing system 110 with the boilerplate assembly 120 installed, and still other examples comprise just the boilerplate assembly 120 by itself.

In FIG. 1, some physical attachments or engagements between components are illustrated by double solid lines extending between the boxes depicting the components. Contact between components and/or heat conduction pathways between components is illustrated by single solid lines extending between the boxes depicting the components, with the arrow indicating the direction of heat flow during normal usage. Flow paths of liquid and/or fluidic connections between two components are depicted using dash-lined arrows extending between the boxes depicting the components, with the arrow indicating a direction of the flow. Vapor/gas flow paths are depicted using dot-lined arrows, with the arrow indicating a direction of the flow.

As shown in FIG. 1, the system comprises an immersion tank 101. The immersion tank 101 comprises a tub or container or similar structure configured to provide two-phase immersion cooling to information processing system such as the system 110. The tank 101 contains a coolant configured for two-phase immersion cooling, meaning that the coolant is electrically non-conducting (e.g., a dielectric) and has a boiling point which is at or near a desired operating temperature of the components of the information processing systems, thus allowing the coolant to change between liquid and vapor (gas) phases during operation. Accordingly, during operation, the tank 101 will contain a liquid phase of the coolant, which collects together in a liquid phase coolant pool 102 in the tank 101, and a vapor phase of the coolant, which collects in a vapor-phase coolant volume 103 above the pool 102.

The liquid-holding portion of the tank 101 is configured to receive one or more information processing systems (e.g., servers), such as the information processing system 110, immersed in the liquid-phase coolant pool 102. In this context, “immersed” means that at least the system board is submerged in the pool 102. In some examples, the entirety of each information processing system 110 may be fully submerged. In other examples, a small portion of a system 110, such as a support bracket which supports the system, may protrude out of the pool 102. The immersion of the system 110 in the liquid coolant pool 102 is suggested by the white arrow in FIG. 1. Note that in FIG. 1 the box representing the system 110 is not drawn inside the box depicting the pool 102 because FIG. 1 is schematic in nature and does not depict positional relationships in this manner.

The immersion tank 101 may also include a cooler 104 configured to cool the vapor in the vapor-phase coolant volume 103. For example, the cooler 104 may include a cold plate which is exposed to the vapor and which is also thermally coupled to an external cooling source, such as a facility cold water line, which removes heat from the cold plate. The cooler 104 may be keep cold enough to promote condensation thereon of the vapor phase coolant back into the liquid phase. The cooler 104 may be located within the vapor-phase coolant volume 103, but in FIG. 1 the box representing the cooler 104 is not drawn inside the box representing the volume 103 because FIG. 1 is schematic in nature and does not show positional relationships in this manner.

The information processing system 110 may comprise a server, networking device, or other system configured to process digital information. The system 110 comprises a system board 111 (e.g., motherboard) to which a CPU 112 is mounted. The system board 111 may also include other electronic components (not illustrated), including one or more additional CPUs, memory modules, etc. The system may also include mounting features 113 arranged around the CPU 112, which will be described in more detail below. The system 110 may also comprise a chassis 115, which supports the system board 111. In some examples, the chassis 115 houses (encloses) the system board 111 and other components of the system 110, while in other examples the chassis 115 does merely supports the system board 111 without housing it (such as a tray). In other examples, the chassis 115 may be omitted. As previously mentioned, FIG. 1 is schematic in nature, and thus does not show the structural details of the chassis 115 or system board 111 or their positional relationships to one another or to the other components.

The boilerplate assembly 120 may be installed as part of the information processing system 110. The boilerplate assembly 120 comprises a boilerplate 121, a manifold 130, and mounting features 125.

The boilerplate 121 comprises a thermally conductive body with a generally plate-like shape, meaning that the body has two broad and generally planar faces which are disposed opposite from and parallel to one another and a number of narrow edge surfaces extending between and connecting the two broad planar faces. Moreover, the width and length dimensions of this body, which are parallel to the broad faces thereof, both greatly exceed (e.g., 5 or more times larger than) a thickness dimension of the body, which is perpendicular to the broad faces thereof. In some examples, the boilerplate 121 is formed from a plate of thermally conductive metal, such as copper, aluminum, steel, etc. In some examples, the boilerplate 121 may be formed from, or comprise within it, a vapor chamber.

The two broad faces of the plate-like body of the boilerplate 121 include a first face 122 and a second face 123. In an installed state, the first face 122 is thermally coupled with (e.g., placed in contact with) the CPU 112, such that heat generated by the CPU 112 is transferred via conduction into the boilerplate 121. The heat is then transferred from the first face 122 through the thickness of the plate 121 to the second face 123. In examples where the boilerplate 121 comprises a plate of solid metal, the heat is transferred through the thickness of the plate 121 via conduction. In examples where the boilerplate 121 comprises a vapor chamber, the heat is transferred through the thickness of the plate 121 via conduction and a vapor change heat transport cycle.

In an installed state of the boilerplate 121 in the system 110 and an immersed state of the system 110 in the tank 101, the second face 123 of the boilerplate 121 is exposed to (i.e., in contact with) the liquid coolant in the pool 102. Thus, heat is transferred from the second face 123 into the liquid coolant. Eventually, the liquid coolant adjacent the second face 123 becomes hot enough to boil. As the liquid boils, the conversion from liquid to vapor face removes even more heat from the boilerplate 121 due to the latent heat of vaporization. The newly formed vapor then bubbles up through the pool 102 and into the volume 103 (as shown by the dotted-line arrows in FIG. 1), where it will eventually come into contact with the cooler 104 and condense back into liquid form, releasing its heat into the cooler 104. The condensed and cooled liquid then drips back down in the pool 102.

The boilerplate 121 may also comprise a boil-enhancing mesh 124. This mesh is disposed on, or formed as part of, the second face 123 of the boilerplate 121. The mesh 124 is configured to increase the rate of boiling of the liquid coolant, for example by increasing the surface area of the second face 123.

The manifold 130 comprises a hollow manifold body 131 which has an interior chamber 132 (e.g., a bore or empty volume contained within the body 131), an inlet 134 fluidically coupling the interior chamber 132 to an external environment, and a plurality of nozzles 133 fluidically coupling the interior chamber 132 to the external environment. Thus, the manifold 130 is configured to allow an input stream of liquid from the external environment to flow into the interior chamber 132 via the inlet 134 and then to output that liquid from the interior chamber 132 back into the external environment as a plurality of output streams via the nozzles 133. An opening in the manifold body fluidically connects the inlet 132 to the interior chamber 132. The inlet 132 may be a liquid coupling or liquid fitting configured to couple with a liquid conduit 141 (e.g., a hose, a pipe, a tube, or any other liquid conduit). Thus, the inlet 132 may include coupling features to facilitate this coupling. Examples of such liquid couplings/fittings include hose barbs, threaded fittings, compressing fittings, quick disconnects (QD), and other liquid couplings/fittings. Examples of the coupling features of these fittings may include barbs, threads, gaskets, quick disconnect features (springs, poppets, etc.), etc.

In some examples, the manifold 130 is attached to the boilerplate 121. More specifically, in some examples at least part of the manifold 130 (e.g., the manifold body 131) is integrally connected to the boilerplate 121, meaning they are formed as parts of the same unitary (monolithic) body. For example, a portion of manifold 130 and the boilerplate 121 may be cast together in the same casting, machined from the same block of metal (e.g., copper, aluminum, etc.), or formed together in an additive manufacturing process (e.g., 3D printing). In other examples, the manifold 130 may be formed as a separate piece which is attached to the boilerplate 121, for example via fasteners, heat staking, adhesives, welding, brazing, or other fastening mechanisms. The manifold 130 is attached to the boilerplate 121 in a manner that aligns the nozzles 133 relative to the boilerplate 121 such that the streams of liquid ejected from the nozzles 133 are directed at the second face 123. In particular, in some examples, some (or all) of the nozzles 133 are arranged to eject their streams towards the mesh 124 (if present). In some examples, the nozzles 133 may have relatively narrow openings (as compared to the size of an opening of the inlet) such that they expel their stream of liquid at relatively high velocity. The streams of liquid may disturb the mixed flow region in and around the second face 123, specifically the mixed flow region in the mesh 124 if present. The mixed flow region is a region where vapor and liquid mix. This mixing changes the boiling characteristics of the region in a way which can further increase the rate of boiling, and thus further improve thermal performance. Furthermore, the streams of coolant also create forced convection of the liquid phase coolant in the region, which further reduces thermal resistance and increases thermal performance. Thus, the boilerplate assembly 120 allows for the temperatures of the high-power components to be greatly reduced as compared to a passive two-phase immersion cooling without the boilerplate assembly.

The boilerplate assembly 120 may further include mounting features 125 which are configured to mount the boilerplate 121 to the system board 111 and/or chassis 115. The mounting features 125 may include elements which are separate from the boilerplate 121, elements which are part of the boilerplate, or a combination of these. For example, the mounting features 125 may include a set of fasteners (e.g., screws, bolts, etc.) and a corresponding set of holes in the boilerplate through which the fasteners may extend. As another example, the mounting features 125 may include a latching mechanism which is formed into, or attached to, the boilerplate, such as a half-turn or quarter-turn latch or any other desired latch. As another example, the mounting features 125 may include retainers (e.g., spring clips) which are attached to the system board 111 and which can be moved into engagement with the boilerplate 121. In some examples, the mounting features 125 are configured to engage with mounting features 113 of the system board 111. For example, if the mounting features 125 include screws, then the mounting features 113 may comprise threaded holes/nuts configured to receive the screws. As another example, if the mounting features 125 include latches, the mounting features 113 may include latch receptacles or complementary latch elements configured to engage with the latches. In other examples, the mounting features 125 are part of the system board, in which case the mounting features 113 may be omitted.

In some examples, the mounting features 113 may be the same mounting features which are used for mounting an air-cooled heat sink to the CPU 112. In such examples, the mounting features 125 of the boilerplate assembly 120 may be configured to mount to these same mounting features 113. In other words, the mounting features 125 of the boilerplate assembly 120 may have locations and attachment mechanisms that mimic those of an air-cooled heat sink. This can be useful in some circumstances where it is desired to convert a system which was originally designed for air cooling into a state in which it can be used in immersion cooling. For example, to convert the system, the fans, air-cooled heatsink, airflow baffles, and other air-cooling paraphernalia that may have been part of the system may be removed, and in their place the boilerplate assembly 120 may be added.

The system 110 may also comprise a pump 140 and liquid conduits 141, which are configured to supply the input stream of liquid coolant to the manifold 130. The pump 140 is configured to draw some of the liquid coolant from the pool 102 and force the liquid to flow into and through the manifold 130, thereby generating the output streams ejected out of the nozzles 133 towards the second face 123, as shown by the dash-lined arrows in FIG. 1. Specifically, pump 140 may be coupled to the inlet 134, either directly or via one or more liquid conduits 141. The pump 140 may be powered by the same power source (not illustrated) which powers the system board 111, such as a power supply unit.

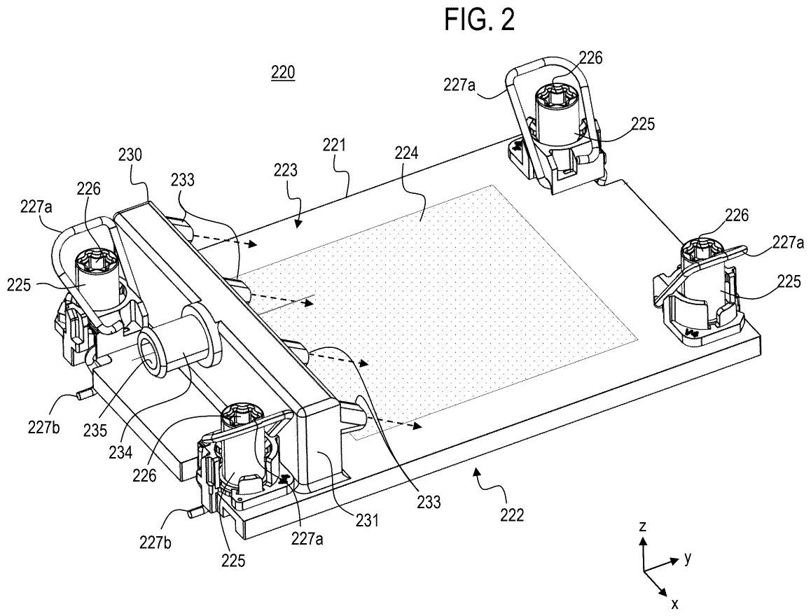

Turning now to FIGS. 2-7, an example boilerplate assembly 220 will be described. The boilerplate assembly 220 is an example implementation of the boilerplate assembly 120 described above. Thus, some components of the boilerplate assembly 220 are similar to (e.g., example implementations or configuration of) corresponding components already described above, and thus the descriptions of the components of the boilerplate assembly 120 above are applicable to the similar components of the boilerplate assembly 220, and duplicative descriptions of certain aspects of the boilerplate assembly 220 may thus be omitted. Corresponding components may be referred to using reference numbers having the same last two digits, such as 121 and 221. It should be understood that the boilerplate assembly 220 is but one possible implementation of the boilerplate assembly 120, and the boilerplate assembly 120 is not limited to the boilerplate assembly 220. Similarly, the individual components of the boilerplate assembly 220 are examples of the corresponding individual components of the boilerplate assembly 120, but the individual components of the boilerplate assembly 120 are not limited to the corresponding components of the boilerplate assembly 220.

The order in which components of the boilerplate assembly 220 are described below is chosen to aid in understanding the structural and functional relationships between the components. However, the logical order which best aids this understanding is not necessarily the same as the order in which the components appear in the drawings. Thus, FIGS. 2-7 will not be described in strict sequence below. Instead, as aspects of the boilerplate assembly are described, certain figures that are thought to be most helpful to understanding the particular aspect under discussion will be called out, even if that requires moving back and forth between the drawings out of order.

As shown in FIGS. 2-4, the boilerplate assembly 220 comprises a boilerplate 221, a manifold 230 coupled to the boilerplate 221, and mounting features 225 coupled to the boilerplate 221.

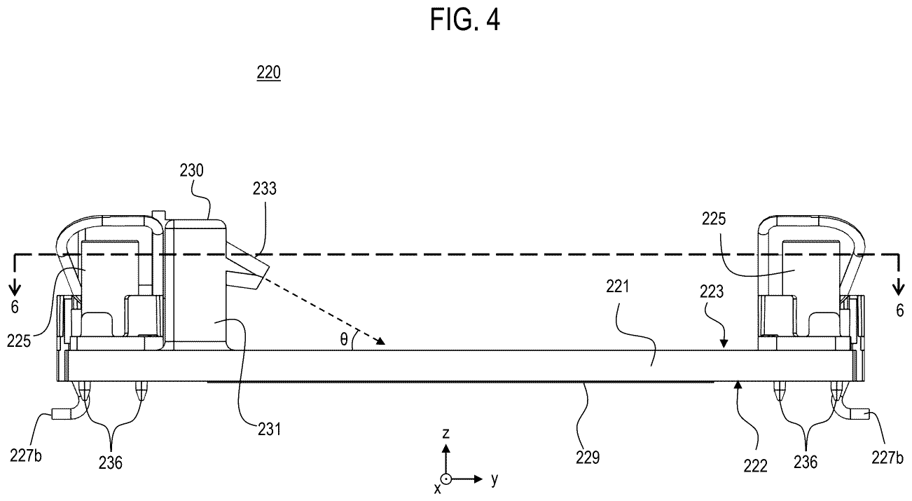

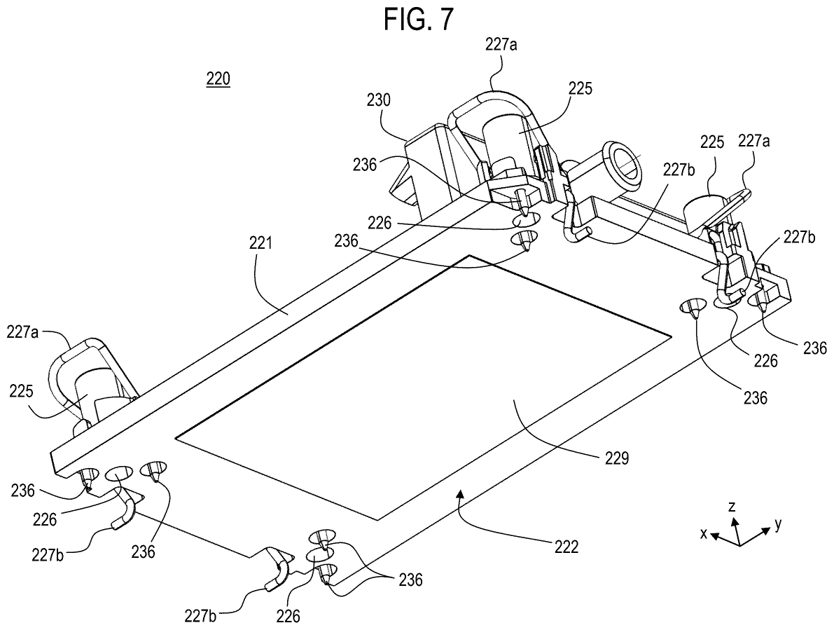

In this example, the boilerplate 221 comprises a metal (e.g., copper) plate with a first face 222 and a second face 223 opposite the first face 222. The first face 222 is configured to be thermally coupled with a CPU of an information processing device, whereas the second face is configured to be exposed to liquid coolant in a pool of an immersion cooling tank when the information processing device is immersed therein. In some examples, a thermal interface material (TIM) 229 may be disposed on the first face 222, as shown in FIGS. 4 and 7. The TIM 229 may be, for example, a graphite pad/mesh, a malleable metal foil (e.g., indium foil), a carbon nano-tube mesh, or any other TIM which is compatible with (e.g., which is not dissolved by or reactant with) the liquid coolant. When the boilerplate 221 is installed on a CPU, the TIM 229 sits between the first face 222 and the CPU and is in mutual contact with both, such that the TIM 229 thermally couples the first face 222 with the CPU. In some examples, the TIM 229 may be omitted, in which case the first face 222 may directly contact the CPU. The boilerplate 221 may also comprise, in some examples, a boil-enhancing mesh 224 disposed on, or formed in, the second face 223. In some examples, the mesh 224 may be omitted.

As shown in FIGS. 2-4, the manifold 230 comprises a manifold body 231, an inlet 134 coupled to the body 231, and four nozzles 233 coupled to the body 231. In some examples, the inlet 134 and/or the nozzles 133 are integrally formed with the body 231, such as via additive manufacturing, casting/molding, etc. In other examples, the inlet 134 and/or the nozzles 133 may be formed separately from the body 231 and then later attached to the body 231 via adhesives, heat stacking, welding, friction fitting, mechanical fasteners, or other fastening techniques. The body 231 is attached to the boilerplate 221. In the illustrated example, the body 231 has a box-like shape, i.e., a rectangular prism shape, with a bottom side thereof being attached to the boilerplate 221. In some examples, the manifold body 231 is formed separately from the boilerplate 221 and is attached thereto by adhesive, heat staking, welding, mechanical fasteners, or other fastening techniques. In other examples, the manifold body 231 is formed integrally with the boilerplate 221, such as via additive manufacturing, casting, etc.

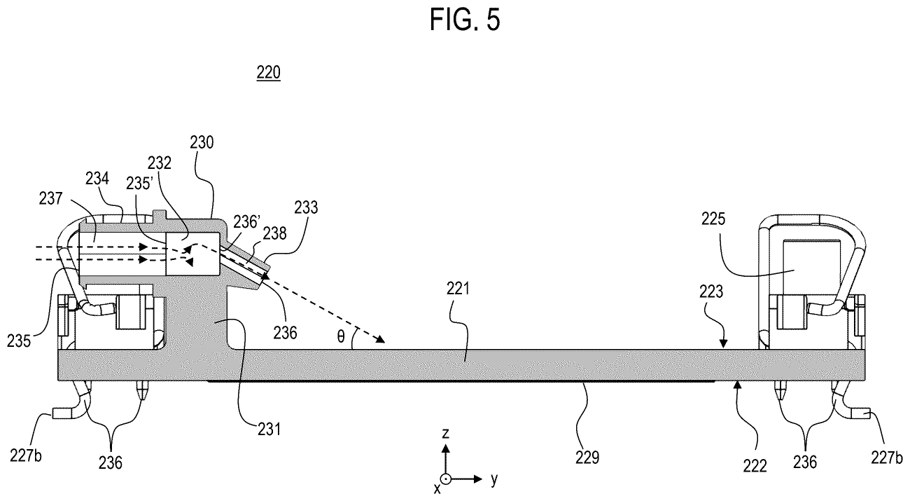

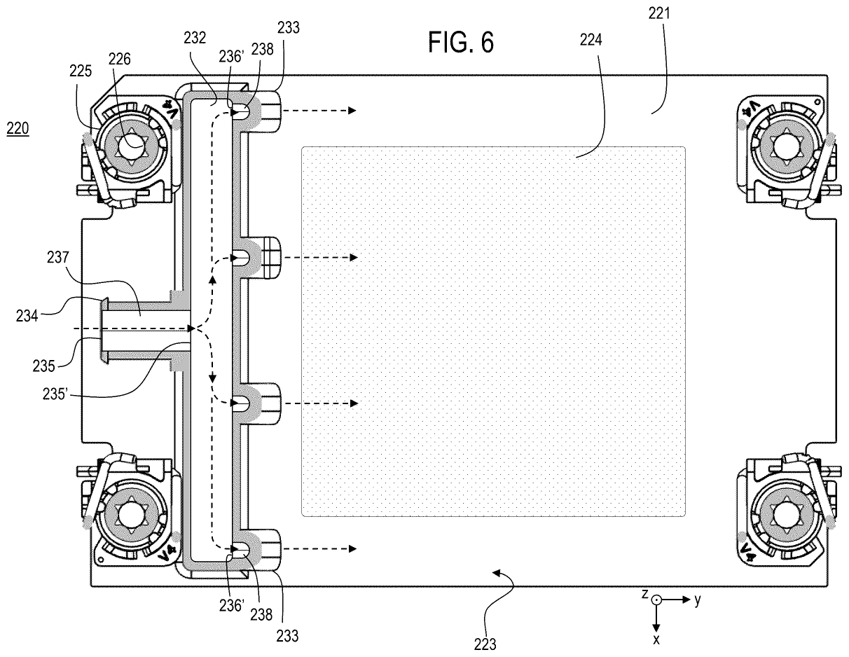

As shown in FIGS. 5 and 6, the manifold body 231 is hollow, having an internal chamber 132 comprising an empty volume/space which can receive liquid coolant. Furthermore, the inlet 234 comprises an inlet opening 235 which is to receive an input stream of liquid coolant inputted to the manifold 230 and the nozzles 233 each comprise outlet openings 236 which are to eject the input liquid coolant from the manifold as multiple output streams, with the internal chamber 132 being arranged to fluidically connect the inlet opening 235 of the inlet 234 with the outlet openings 236 of the nozzles 233. More specifically, the internal chamber 132 has an opening 235′ and the inlet 234 is coupled to the body 231 at the opening 235′ such that an internal channel 237 of the inlet 234 is fluidically coupled with the internal chamber 132 via the opening 235′. The internal chamber 132 also has multiple openings 236′ and each of the nozzles 233 is coupled to the body 231 at a corresponding one of these openings 236′ such that an internal channel 238 of the nozzle 233 is fluidically coupled with the internal chamber 132 via the opening 236′. Thus, an input stream of liquid from an environment external to the manifold 230 can enter the manifold by flowing into the channel 237 of the inlet 234 via opening 235, then the liquid may flow through the channel 237, pass into the chamber 232 via the opening 235′, flow through the chamber 232, divide into multiple output streams which pass out of the chamber 232 and into the channels 238 via the openings 236', and then the output streams of liquid may be ejected from the manifold 230 by passing out of the channels 238 via openings 236. These liquid flow paths are depicted in the figures, particularly in FIGS. 5 and 6, as dash-lined arrows.

In this example, the inlet 234 has the form of a hose barb fitting configured to couple with a hose, which may in turn be coupled to a pump which pumps the liquid coolant from an immersion tank into the manifold 230. In other examples, the inlet 234 could be replaced with any other desired fluid coupling, such as a threaded coupling, quick-disconnect fluid coupling, or others.

As shown in FIGS. 4 and 5, the nozzles 233 are arranged to direct the output streams of liquid coolant expelled therefrom towards the second face 223. More specifically, the nozzles 233 direct the output streams at an acute angle θ relative to the second face 223, wherein 0°<θ<90°. References herein to the directions or orientations of the output streams should be understood as referring specifically to their directions at, or immediately after, the output openings of the nozzles, unless noted otherwise. More specifically, the angle θ may be measured relative to a central axis of the output stream at a given point in, or immediately after, the opening 236, wherein this central axis is disposed in the center of the flow stream is aligned with an average flow direction of the stream at that point. In the illustrated example, θ is about 30°. In some examples, θ is between 10° and 75°. In some examples, θ is between 20° and 40°. In some examples, θ is between 25° and 35°. In some examples, θ is between 15° and 25°. In some examples, θ is between 35°and 50°. In some examples, θ is between 50° and 75°. All of the ranges mentioned above are inclusive of the mentioned endpoints, unless noted otherwise. In some examples, the directionality of the flow of expelled liquid may be affected by the direction in which the channel 238 extends and/or by the shape and orientation of the opening 233.

In the illustrated example, there are four nozzles 233, but in other examples, there may be more nozzles 233 (e.g., five, six, or any number) or fewer nozzles (e.g., three, two). In the illustrated example, there is equidistant spacing between the nozzles 233 along the x-axis, but in other examples, the spacing between nozzles 233 is not necessarily equidistant. In the illustrated example, the nozzles 233 are spread out along the x-axis such that the space spanned by the nozzles 233 covers substantially all (e.g., 80% or more) of the width of the plate 221. In other examples, the spread of the nozzles 233 along the x-axis may be substantially less than (e.g., less than 80% of) the width of the plate 221. In the illustrated example, there is one row of nozzles 233 extending along the x-axis with all the nozzles 233 having a similar height (along the z-axis) above the face 223, but in other examples, one or more nozzles 233 may be disposed at different heights above the face 223 than one or more other nozzles 233. In the illustrated example, all of the nozzle 233 expel liquid at the same angle θ, but in other examples one or more nozzles 233 may expel liquid at an angle different from one or more other nozzles 233. For example, in one implementation a first set of nozzles 233 may expel liquid at a first angle θ₁ while a second row of nozzles 233 may expel liquid at a second angle θ₂ wherein θ₂<θ₁, such that the central axis of the liquid stream ejected from the first nozzles 233 intersects with a closer section of the face 224 while the central axis of the liquid stream ejected from the second nozzles 233 intersects with a farther section of the face 224. In the illustrated example, all of the nozzle 233 have the same shape and configuration as one another, including having the same size and same shape output openings 236, and therefore all of the ejected streams of liquid have substantially similar characteristics (e.g., the same stream width, the same flow speed, etc.). In other examples, one or more nozzles 233 may have a different shape or configuration than one or more other nozzles 233 and thus their respective ejected streams may differ from one another in one or more characteristics. For example, a first set of nozzles 233 may have larger output openings 236 than a second set of nozzles 233, resulting in the streams ejected by the first set of nozzles 233 having larger diameter and being slower and the streams ejected by the second set of nozzles 233 having smaller diameter and being faster. In the illustrated examples, some of the nozzles 233 produce streams whose central axes intersect directly with the mesh 224 and some of the nozzles produce streams whose central axes do not intersect directly with the mesh 224. In other examples, all of the nozzles 233 produce streams whose central axes intersect directly with the mesh 224. In other examples, none of the nozzles 233 may produce streams whose central axes intersects directly with the mesh 224. In the illustrated example, the openings 236 of the nozzles 223 are circular in cross-section, thus each nozzle 223 generates a single streams which is essentially circular in cross-section. In other examples, the openings 236 may have other cross-sectional shapes, such as an ellipse, a rectangle, etc., which may produce different shapes of output streams. Furthermore, in some examples more than one opening 236 may be provided per nozzle 223, which may allow for multiple smaller output streams to be generated by a single nozzle 223.

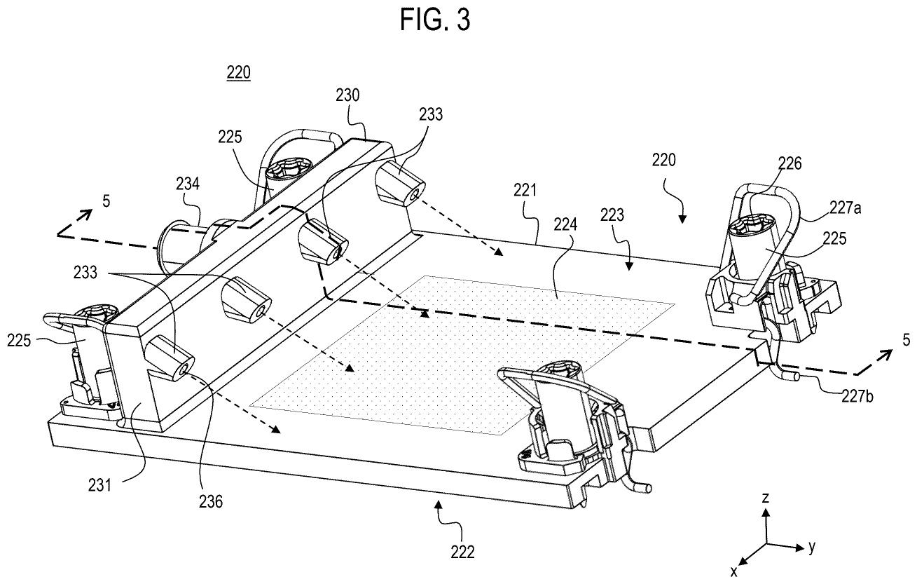

As shown in FIGS. 2-7, four sets of the mounting features 225 may be provided, with each being attached to a corresponding corner of the boilerplate 221. In other examples, more or fewer sets of mounting features 225 could be provided. In the illustrated example, each set of mounting features 225 may include multiple mounting features, including a spring clip 227, a fastener receiver 226, and alignment pins 236. As shown in FIGS. 2 and 3, each spring clip 227 comprises a wire which is bent to form a shape having a handle end 227a and an engagement end 227b. The engagement end 227b protrudes below the first face 222 of the boilerplate 221, as shown in FIG. 4, and has a hooked shape configured to engage with a complimentary receiver structure on a system board or chassis of an information processing device to couple the boilerplate 221 to the system board. The handle end 227a is configured to be grasped by a user and moved, with the movement resulting in elastic deformation of the spring clip 227 and therefore the generation of a restoring spring force which opposes the movement and urges the handle 227a back towards a resting state. When the handle end 227a is moved, this causes movement of the engagement end 227a. This movement of the engagement end 227a can facilitate engagement or disengagement from the receiver of the system board. Thus, for example, a user may squeeze the handle ends 227a of two opposing mounting features 225 towards one another, which may move the engagement ends 227a of those two mounting features 225 into a disengaged position which may allow for installation of the boilerplate 221, and then the user may release the handle ends 227a allowing the spring force to return them to their resting positions and thereby moving the engagement ends 227a into an engaged state. The alignment pins 236, best seen in FIG. 7, extend through the plate 221 and protrude below the face 222, and may engage with corresponding apertures in the system board or chassis to facilitate alignment of the plate 221 relative to the CPU. The fastener receiver 226 comprises a bore in a column through which a fastener or post may extend. The fastener may be used in addition to, or in lieu of, the spring clips 227 to fasten the boilerplate 221 to the system board or chassis.

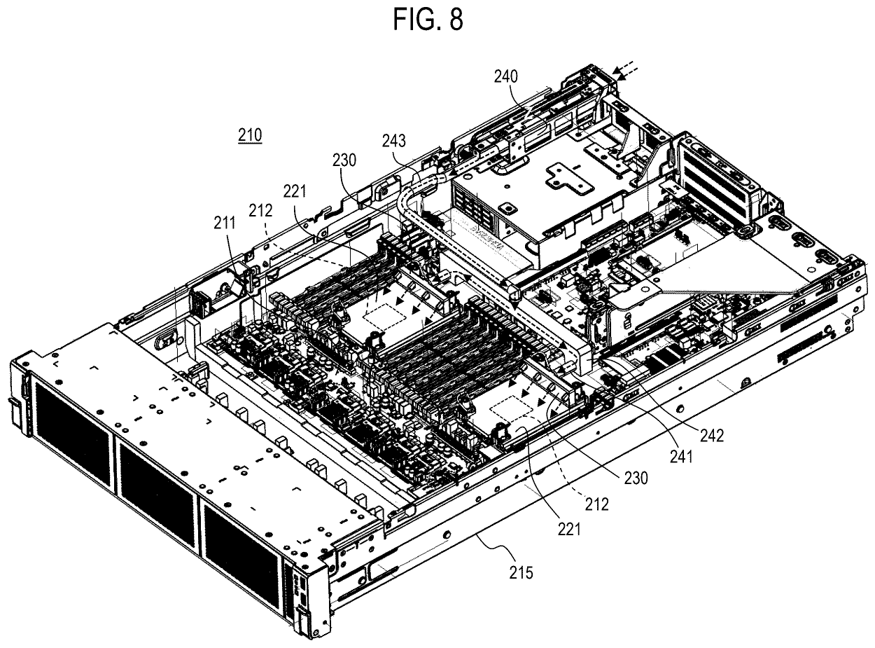

FIG. 8 illustrates an example information processing system 210 in which the boilerplate assembly 210 described above may be utilized. The system 210 is a server which comprises a chassis 215 housing a system board 211, as well as various peripheral devices (not labeled) such as drives, expansion cards, etc. The system board 211 has two CPUs 212 mounted thereto, and two boilerplate assemblies 220 are mounted to the CPUs 212, respectively (the actual CPUs 212 are not visible in the figure because they are below the boilerplates 221, but their general locations are indicated by dashed lines in FIG. 8). In this example, the mounting features 225 of the boilerplates 221 engaged with mounting features (not visible) of the system board, thereby coupling the boilerplate assemblies 220 to the system board.

In addition, the system comprises a pump 240 and liquid conduits connecting the pump 240 to the manifolds 230 of the boilerplate assemblies 220. In FIG. 1, these liquid conduits include a first tube 243, a distribution manifold 242, and second tubes 241. The first tube 243 fluidically connects the pump to the distribution manifold 242, and the two second tubes 241 fluidically connect the distribution manifold 242 to the two boilerplate assemblies 220, respectively. Thus, when the system 210 is immersed in a pool of liquid coolant, the pump 240 may draw in coolant from the pool and cause the liquid to flow into the manifolds 230 of the boilerplate assemblies 220 via the first tube 243, the distribution manifold 242, and the second tubes 241 (liquid flow paths are depicted in FIG. 8 by dash-lined arrows).

FIG. 8 illustrates an example immersion cooling system 200 for immersion cooling information processing systems such as the system 210. The system 200 comprises an immersion cooling tank 101 configured to receive multiple information processing systems therein and immerse the systems in liquid coolant. The system 200 also includes at least one such information processing system, namely the system 210.

The immersion cooling tank 101 comprises a base 105 and a lid which are connected to one another in an air-tight manner (e.g., via seals 107) to enclose an interior volume. In the tank, there is a pool 102 of liquid phase coolant and, above the pool 102, a volume 103 comprising vapor-phase coolant (in some cases, other gases, such as air, may also be present in the volume 103). The tank 101 also comprises a cooler 104 disposed in the volume 103. The cooler may comprise a plate or a radiator/heat exchanger which is cooled by an external cooling source. For example, an external chilled liquid source may flow liquid through the cooler 104 via liquid couplings 108, thereby maintaining the cooler 104 at a desired temperature, which is at or lower than a condensation point of the vapor phase coolant.

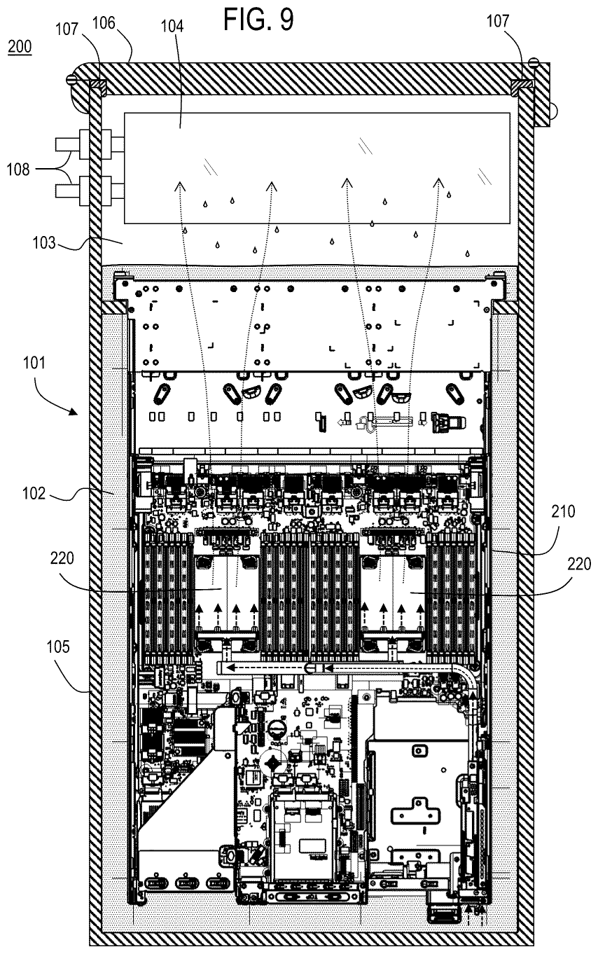

The system 210 is immersed within the liquid coolant in the pool 102. As the system 210 operates, it generates heat. This heat is absorbed by the liquid coolant in the pool 102, and eventually some of the liquid boils, converting into vapor. In this manner, the components are cooled. In particular, the boilerplate assemblies 220 are configured to facilitate this boiling, allowing the heat generated by the CPUs to be more readily transferred into the coolant. The newly formed vapor then bubbles up through the liquid pool 102 into the volume 103, as suggested by the dotted-line arrows in FIG. 9. The vapor carries with it the heat which it previously absorbed from the boilerplate assembly 220 and other components. Vapor in the volume 103 then eventually moves, via natural convection, into contact with the cooler 104. Because the cooler 104 is colder than the condensation point of the coolant, the vapor coolant that contacts the cooler 104 condenses back into liquid form, transferring heat into the cooler 104 and reducing the temperature of the now-condensed liquid back down below the boiling point. This condensed and cooled liquid coolant then drips back down into the pool 102, as suggested by the droplets depicted in FIG. 9, where it can absorb more heat and start the cycle again. As noted, the cooler 104 absorbs heat from the condensing vapor, and therefore cooling needs to be provided to the cooler 104 (such as via the circulation of the chilled liquid through the cooler) in order to remove this absorbed heat and keep the temperature of the cooler 104 below the condensation point of the coolant, allowing it to continue condensing vapor.

It is to be understood that both the general description and the detailed description provide examples that are explanatory in nature and are intended to provide an understanding of the present disclosure without limiting the scope of the present disclosure. Various mechanical, compositional, structural, electronic, and operational changes may be made without departing from the scope of this description and the claims. In some instances, well-known circuits, structures, and techniques have not been shown or described in detail in order not to obscure the examples. Like numbers in two or more figures represent the same or similar elements.

In addition, the singular forms “a”, “an”, and “the” are intended to include the plural forms as well, unless the context indicates otherwise. Moreover, the terms “comprises”, “comprising”, “includes”, and the like specify the presence of stated features, steps, operations, elements, and/or components but do not preclude the presence or addition of one or more other features, steps, operations, elements, components, and/or groups. Components described as coupled may be electronically or mechanically directly coupled, or they may be indirectly coupled via one or more intermediate components, unless specifically noted otherwise. Mathematical and geometric terms are not necessarily intended to be used in accordance with their strict definitions unless the context of the description indicates otherwise, because a person having ordinary skill in the art would understand that, for example, a substantially similar element that functions in a substantially similar way could easily fall within the scope of a descriptive term even though the term also has a strict definition.

And/or: Occasionally the phrase “and/or” is used herein in conjunction with a list of items. This phrase means that any combination of items in the list—from a single item to all of the items and any permutation in between—may be included. Thus, for example, “A, B, and/or C” means “one of {A}, {B}, {C}, {A, B}, {A, C}, {C, B}, and {A, C, B}”.

Elements and their associated aspects that are described in detail with reference to one example may, whenever practical, be included in other examples in which they are not specifically shown or described. For example, if an element is described in detail with reference to one example and is not described with reference to a second example, the element may nevertheless be claimed as included in the second example.

Unless otherwise noted herein or implied by the context, when terms of approximation such as “substantially,” “approximately,” “about,” “around,” “roughly,” and the like, are used, this should be understood as meaning that mathematical exactitude is not required and that instead a range of variation is being referred to that includes but is not strictly limited to the stated value, property, or relationship. In particular, in addition to any ranges explicitly stated herein (if any), the range of variation implied by the usage of such a term of approximation includes at least any inconsequential variations and also those variations that are typical in the relevant art for the type of item in question due to manufacturing or other tolerances. In any case, the range of variation may include at least values that are within ±1% of the stated value, property, or relationship unless indicated otherwise.

Further modifications and alternative examples will be apparent to those of ordinary skill in the art in view of the disclosure herein. For example, the devices and methods may include additional components or steps that were omitted from the diagrams and description for clarity of operation. Accordingly, this description is to be construed as illustrative only and is for the purpose of teaching those skilled in the art the general manner of carrying out the present teachings. It is to be understood that the various examples shown and described herein are to be taken as exemplary. Elements and materials, and arrangements of those elements and materials, may be substituted for those illustrated and described herein, parts and processes may be reversed, and certain features of the present teachings may be utilized independently, all as would be apparent to one skilled in the art after having the benefit of the description herein. Changes may be made in the elements described herein without departing from the scope of the present teachings and following claims.

It is to be understood that the particular examples set forth herein are non-limiting, and modifications to structure, dimensions, materials, and methodologies may be made without departing from the scope of the present teachings.

Other examples in accordance with the present disclosure will be apparent to those skilled in the art from consideration of the specification and practice of the invention disclosed herein. It is intended that the specification and examples be considered as exemplary only, with the following claims being entitled to their fullest breadth, including equivalents, under the applicable law.

What is claimed is:

1. A boilerplate assembly for two-phase immersion cooling of an information processing system, comprising:
a boilerplate comprising a first face and a second face opposite the first face,
wherein the first face is configured to, in an installed state of the boilerplate assembly in the information processing system, thermally couple with a heat generating component of the information processing system,
wherein the second face is configured to, in an installed state of the boilerplate assembly in the information processing system and an immersed state of the information processing system in a pool of liquid coolant in an immersion cooling tank, contact and facilitate boiling of the liquid coolant, and
a manifold attached to the boilerplate and comprising a plurality of nozzles, wherein the manifold is configured to, in the installed state of the boilerplate assembly in the information processing system and the immersed state of the information processing system, receive an input stream of the liquid coolant and expel output streams of the liquid coolant via the nozzles, wherein the output streams are directed towards the second face of the boilerplate.

2. The boilerplate assembly of claim 1,
wherein the boilerplate comprises a mesh on or in the second face configured to increase a rate of boiling of the liquid coolant.

3. The boilerplate assembly of claim 2,
wherein at least some of the nozzles are configured to direct their respective output streams towards the mesh.

4. The boilerplate assembly of claim 3,
wherein at least some of the nozzles are configured to cause their respective output streams to disturb a mixed flow region in and around the mesh in a manner that further increases the boiling rate of the liquid coolant.

5. The boilerplate assembly of claim 1,
wherein at least some of the nozzles are configured to cause their respective output streams to disturb a mixed flow region at the second face in a manner that increases the boiling rate of the liquid coolant.

6. The boilerplate assembly of claim 1,
wherein the boilerplate comprises metal plate.

7. The boilerplate assembly of claim 1,
wherein the boilerplate comprises a vapor chamber.

8. The boilerplate assembly of claim 1,
wherein the plurality of nozzles are arranged to eject the streams at an acute angle relative to the second face.

9. The boilerplate assembly of claim 8,
wherein the acute angle is between 10°and 75°.

10. The boilerplate assembly of claim 8,
wherein the acute angle is between 25°and 35°.

11. The boilerplate assembly of claim 1, further comprising:
one or more mounting features configured to mount the boilerplate assembly to a system board of the information processing device.

12. The boilerplate assembly of claim 11,
wherein the heat generating component is a central processing unit (CPU) and the one or more mounting features are configured to engage with CPU heatsink mounting features of the system board to mount the boilerplate assembly to the system board.

13. The boilerplate assembly of claim 1,
wherein manifold is integrally connected to the boilerplate.

14. The boilerplate assembly of claim 1,
wherein manifold is formed separately from the boilerplate and is connected to the boilerplate via mechanical fasteners, adhesives, heat staking, welding, brazing, press fitting, friction fitting, or interlocking engagement.

15. The boilerplate assembly of claim 1,
wherein the manifold comprises an inlet comprising a fluid coupling configured to couple with a fluid conduit to receive the input stream.

16. An information processing system comprising:
a system board with a processor mounted thereto;
a chassis supporting the system board;
a pump; and
a boilerplate assembly mounted to the system board and comprising:
a boilerplate comprising a first face thermally coupled with the processor and a second face configured to, in an immersed state of the information processing system in a pool of liquid coolant in an immersion cooling tank, contact and facilitate boiling of the liquid coolant, and
a manifold attached to the boilerplate and comprising a plurality of nozzles, wherein the manifold is configured to, in the immersed state of the information processing system, receive an input stream of the liquid coolant from the pump and expel output streams of the liquid coolant via the nozzles, wherein the output streams are directed towards the second face of the boilerplate.

17. The boilerplate assembly of claim 1,
wherein the boilerplate comprises a mesh on or in the second face configured to increase a rate of boiling of the liquid coolant, and
wherein at least some of the nozzles are configured to direct their respective output streams towards the mesh such that the respective output streams disturb a mixed flow region in and around the mesh in a manner that further increases the boiling rate of the liquid coolant.

18. The boilerplate assembly of claim 1,
wherein at least some of the nozzles are configured to cause their respective output streams to disturb a mixed flow region at the second face in a manner that increases the boiling rate of the liquid coolant.

19. The boilerplate assembly of claim 1,
wherein the plurality of nozzles are arranged to eject the streams at an acute angle relative to the second face.

20. A two-phase immersion cooling system, comprising:
an immersion cooling tank containing a coolant having a liquid phase collected in a pool in the immersion cooling tank and a vapor phase collected in a volume above the pool in the immersion cooling tank, the immersion cooling tank configured to receive multiple information processing systems immersed in the liquid phase of the coolant in the pool,
an information processing system immersed in the liquid phase of the coolant in the pool, the information processing system comprising:
a system board with a processor mounted thereto;
a chassis supporting the system board;
a pump; and
a boilerplate assembly mounted to the system board and comprising:
a boilerplate comprising a first face thermally coupled with the processor and a second face configured to contact and facilitate boiling of the liquid phase of the coolant, and
a manifold attached to the boilerplate and comprising a plurality of nozzles, wherein the manifold is configured to receive an input stream of the liquid coolant from the pump and expel output streams of the liquid coolant via the nozzles, wherein the output streams are directed towards the second face of the boilerplate.
